(19) United States
(12) Patent Application Publication
(10) Pub. No.: US 2009/0033525 A1
(43) Pub. Date: Feb. 5, 2009

(54) GAIN WEIGHTED CODE COMBINING SYSTEM AND METHOD FOR COMBINING THREE BPSK CODES

(76) Inventor: Isaac Ming-En Jeng, Yorba-Linda, CA (US)

Correspondence Address: HARNESS DICKEY & PIERCE, PLC, P.O. BOX 828, BLOOMFIELD HILLS, MI, 48303, US

(21) Appl. No.: 11/831,378

(22) Filed: Jul. 31, 2007

(51) Int. Cl. H03M 5/16

(52) U.S. Cl. 341/57

(57) ABSTRACT

A method and system for generating a composite binary phase shift keying (BPSK) code from three independent component BPSK codes that is representative of each of the three component BPSK codes. According to one embodiment the method involves gain weighting each of first, second and third BPSK codes by its respective code power ratio to form first, second and third gain weighted codes. The first, second and third gain weighted codes are processed in accordance with an algorithm to form a composite BPSK code. The composite BPSK code has a fifty to seventy-five percent probability of matching each one of the component BPSK codes. A system for generating a composite BPSK code from three component BPSK codes is also disclosed.

### CROSS-REFERENCE TO RELATED APPLICATIONS

This application is related to U.S. patent application Ser. No. ______ (Boeing 07-0537; HDP 7784-001070) filed concurrently herewith, and hereby incorporated by reference into the present application.

### STATEMENT OF U.S. GOVERNMENT RIGHTS

The subject matter of the present disclosure was developed at least in part pursuant to a contract with the U.S. Air Force pursuant to contract number FA8807-04-C-0002. The U.S. Government has certain rights in the subject matter of the present disclosure.

### FIELD

The present disclosure relates to binary phase shift keying (BPSK) code combining systems and methods, and more particularly to a combining method and system of three BPSK codes enabling a single, composite BPSK code to be generated that is representative of three BPSK codes.

### BACKGROUND

The statements in this section merely provide background information related to the present disclosure and may not constitute prior art.

Currently, the global positioning system GPS IIF transmits three binary phase shift keying (BPSK) codes using a modulation scheme known in the industry as “Interplex” modulation. The Interplex modulation scheme modulates three BPSK codes such that the modulated signal has a constant power. The GPS III system needs to transmit two additional BPSK codes. However, the transmitted signal still needs to have a constant power.

One option for combining the five signals involves using the Interlace combining scheme. The Interlace combining scheme can be used to combine the three BPSK codes into one, so the original total of five BPSK codes are reduced to three. These three codes can then be modulated using Interplex just like what is presently being done in GPS IIF.

The above technique suffers from certain limitations and drawbacks because it requires complex logic. For one, the existing Interlace combining technique requires a uniform random number generator. Optimum performance of the Interlace combining technique depends on the authenticity (i.e., flatness) of the uniform random number generator (i.e., the degree to which the generated random numbers are uniformly distributed). In addition, when a uniform random number generator is utilized, a mapping table is required to make a selection for the current chip of the composite code between either the majority voted code (the code that is formed by the three component codes on the majority-vote basis) or one of the two BPSK component codes of higher code powers, depending on the magnitude of the random number. This process repeats when a random number is generated.

### SUMMARY

The present disclosure relates to a method and system for generating a composite BPSK code from a plurality of three potentially different component BPSK codes. In one implementation the method involves gain weighting the first, second and third component BPSK codes by its respective code power ratio to form first, second and third gain weighted codes. The first, second and third gain weighted codes are processed in accordance with an algorithm to form a composite BPSK code. The composite BPSK code has a probability of more than fifty percent of matching each one of the component BPSK codes.

In one specific implementation, gain weightings (also known as code power ratios) of the first, second and third BPSK codes involve the operations of:

assigning a(t) to represent the first component BPSK code, where a(t) is a random BPSK code equally likely to be +1 or −1, and has the highest code power of the three component BPSK codes;

assigning b(t) to represent the second component BPSK code, where b(t) is a random BPSK code equally likely to be +1 or −1, and has the second highest code power of the three component BPSK codes;

assigning c(t) to represent the third component BPSK code, where c(t) is a random BPSK code equally likely to represent +1 or −1, and has a code power no more than that of the other two component BPSK codes;

determining code power ratios using the formulas:

$${g}_{a} = \frac{code power of a ( t )}{code power of c ( t )}$$

$${g}_{b} = \frac{code power of b ( t )}{code power of c ( t )}$$

$${g}_{c} = \frac{code power of c ( t )}{code power of c ( t )} = 1$$

and where gₐ, g_{b} and g_{c} are arranged such that:

gₐ≧g_{b}≧g_{c}=1.

As used herein, the term “code power” means the power associated with a specific component BPSK code.

The composite BPSK code is represented by a term x(t), and determined in a chip-synchronous manner by the formula (where * denotes multiplication):

x(t)=sign{└\sqrt{gₐ}a(t)+\sqrt{g_{b}}b(t)+c(t)−\sqrt{gₐ}a(t)*\sqrt{g_{b}}b(t)*c(t)┘}.

A system for generating a composite BPSK code from three component BPSK codes is also disclosed. Advantageously, the system does not require the use of a uniform random number generator or a mapping table.

This present methodology has its unique combining efficiency related to the correlations between the composite BPSK code and each of the component BPSK codes. This combining efficiency, being less than 100%, can be practically interpreted as a reduction of the effective code power for each of the component codes. The correlation between the composite BPSK code and a component code may lie between −1 to 1 inclusive, and shows the resemblance of one with the other. For example, when the correlation is close to 1, it means almost all the chips of the composite BPSK code and the respective chips of the component BPSK code are the same. Likewise when the correlation is close to −1, except that the two are 180-degree out of phase. When the correlation is close to zero, a very low percentage of the composite BPSK code chips and the respective component code BPSK chips are the same.

A method for determining the reduction of the effective code power for each of the component BPSK codes is also disclosed, together with a method for compensating for these reductions.

### BRIEF DESCRIPTION OF THE DRAWINGS

The drawings described herein are for illustration purposes only and are not intended to limit the scope of the present disclosure in any way.

FIG. 1 is a simplified block diagram of one embodiment of a system in accordance with the present disclosure;

FIG. 2 is a flowchart setting forth a plurality of exemplary operations of a method of the present disclosure for determining a composite BPSK code from a plurality of three potentially different component BPSK codes;

FIG. 3 is a table illustrating the probability of matching chips between the composite BPSK code and the component BPSK codes;

FIG. 4 is a table illustrating the probability of matching chips between the composite BPSK code and component BPSK codes;

FIG. 4A illustrates certain ones of major formulas associated with the implementation of the present disclosure;

FIG. 5 is a table illustrating the probability of matching chips between the composite BPSK code and the component BPSK codes;

FIG. 6 is a graph illustrating the matching probability of each component BPSK code against the composite BPSK code over the ranges of gₐ and g_{b};

FIG. 7 is a table illustrating the probability of matching chips between the composite BPSK code and the component BPSK codes;

FIGS. 8A and 8B are graphs illustrating the correlations of the composite BPSK code with itself and with the component BPSK codes;

FIGS. 9A and 9B are graphs illustrating the correlations between the composite BPSK code and the component BPSK codes but for different code power ratios;

FIGS. 10A and 10B are graphs illustrating the correlations between the composite BPSK code and the component BPSK codes for different code power ratios, and highlighting the reduction in correlation between each of the component BPSK codes and the composite BPSK code when the code power ratios are close to the border between the cross-hatched and stippled areas of FIG. 6; and

FIGS. 11A and 11B are additional graphs illustrating the correlation between the composite BPSK code and the component BPSK codes, and how the correlations drop virtually to zero when the code power ratios fall within the stippled area of the graph of FIG. 6; and

FIG. 12 is a diagram illustrating how the power of the composite BPSK code is formed.

### DETAILED DESCRIPTION

The following description is merely exemplary in nature and is not intended to limit the present disclosure, application, or uses.

The present disclosure relates to a method and system for generating a composite binary phase shift keying (BPSK) code from three independent component BPSK codes. The composite BPSK code can then be transmitted as one BPSK code and is a representative of the three component BPSK codes.

Initially the three component BPSK codes are defined by assigning a(t) to represent the first component BPSK code, where a(t) is a random BPSK code equally likely to be +1 or −1, and has the highest code power of the three component BPSK codes. The term b(t) is assigned to represent the second component BPSK code, where b(t) is a random BPSK code equally likely to be +1 or −1, and has the second highest code power of the three component BPSK codes. The term c(t) is assigned to represent the third component BPSK code, where c(t) is a random component BPSK code equally likely to represent +1 or −1, and has a code power no more than that of the other two component BPSK codes.

A code power ratios (also known as gain weightings) associated with each of the component BPSK codes gₐ, g_{b} and g_{c} is then determined by the following formulas

$$\begin{matrix}{g}_{a} = \frac{code power of a ( t )}{code power of c ( t )} & Equaition 1 \\ {g}_{b} = \frac{code power of b ( t )}{code power of c ( t )} & Equaition 2 \\ {g}_{c} = \frac{code power of c ( t )}{code power of c ( t )} = 1 & Equaition 3\end{matrix}$$

and the code powers are in descending order (i.e., power of a(t)≧power of b(t)≧power of c(t), and g_{c} is set equal to 1 (i.e., gₐ≧g_{b}≧g_{c}=1).

Once the code power ratios have been determined, and in view of the fact that g_{c} is set equal to 1, the following algorithm can be used to determine the composite BPSK code:

x(t)=sign{[\sqrt{gₐ}a(t)+\sqrt{g_{b}}b(t)+c(t)−\sqrt{gₐ}a(t)*\sqrt{g_{b}}b(t)*c(t)]} Equation 4

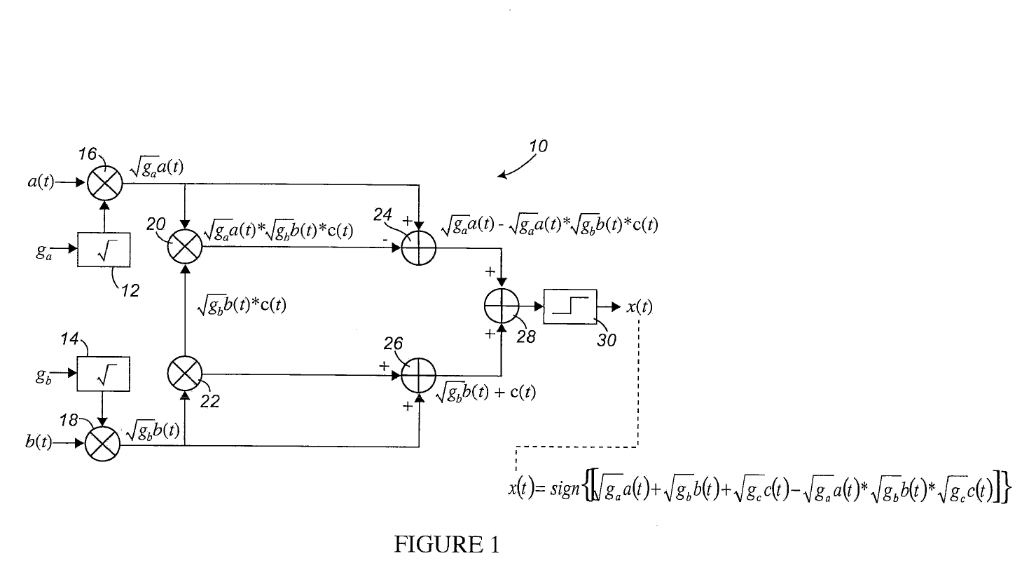

A system 10 in accordance with one embodiment of the present disclosure for implementing Equation 4 is illustrated in FIG. 1. The system 10 makes use of two square root determining circuits 12 and 14, four multiplier circuits 16, 18, 20 and 22, three summing circuits 24, 26 and 28, and a zero threshold comparing circuit 30. Alternatively, some or all of the functions of system 10 may be implemented by a suitable programmed computer processor. For convenience, portions of various equations that are performed by their corresponding components in system 10 are reproduced adjacent to their respective components.

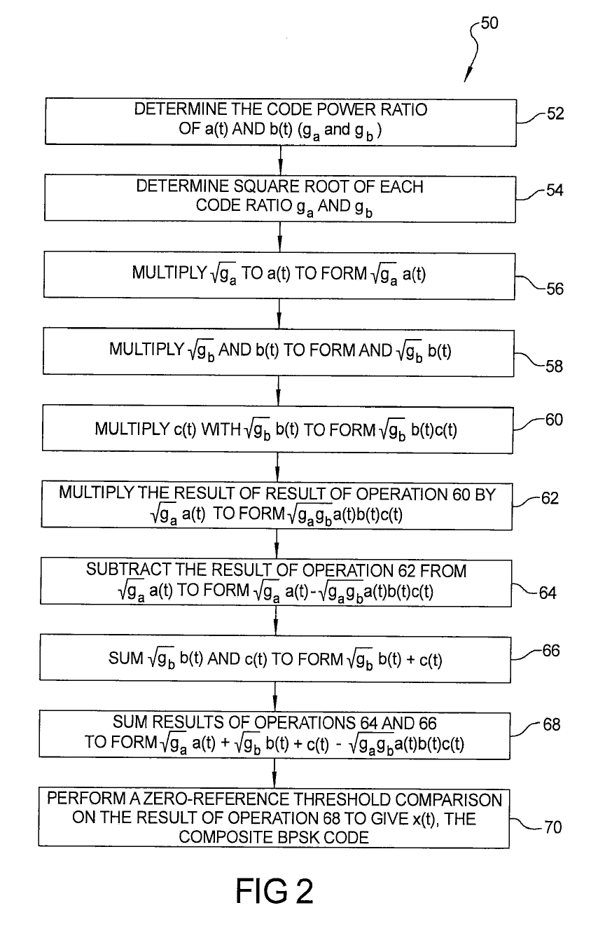

With reference to flowchart 50 of FIG. 2 and the system 10 shown in FIG. 1, the operation of the system 10 will be described. At operation 52, determine the code power ratios gₐ and g_{b} in accordance with the Equations set forth in Equations 1 and 2 above. At operation 54, the square root of each code ratio gₐ and g_{b} is determined using square root determining circuits 12 and 14. At operation 56, multiply \sqrt{gₐ} and a(t) to form \sqrt{gₐ}a(t) using multiplier circuit 16. At operation 58, multiply \sqrt{g_{b}} and b(t) to form and \sqrt{g_{b}}b(t) using multiplier circuit 18. At operation 60, multiply c(t) with \sqrt{g_{b}}b(t) to form \sqrt{g_{b}}b(t)c(t) using multiplier circuit 22. At operation 62, multiply the result of operation 60 by \sqrt{gₐ}a(t) to form \sqrt{gₐg_{b}}a(t)b(t)c(t) using multiplier circuit 20. At operation 64, subtract the result of operation 62 from \sqrt{gₐ}a(t) to form \sqrt{gₐ}a(t)−\sqrt{gₐg_{b}}a(t)b(t)c(t) using summing circuit 24. At operation 66, sum \sqrt{g_{b}}b(t) and c(t) to form \sqrt{g_{b}}b(t)+c(t) using summing circuit 26. At operation 68, sum the results of operation 64 and 66 to form \sqrt{gₐ}a(t)+\sqrt{g_{b}}b(t)+c(t)−\sqrt{gₐg_{b}}a(t)b(t)c(t) using summing circuit 28. At operation 70, perform a zero-reference threshold comparison using zero threshold comparing circuit 30 on the result of operation 68 to give x(t), the composite BPSK code.

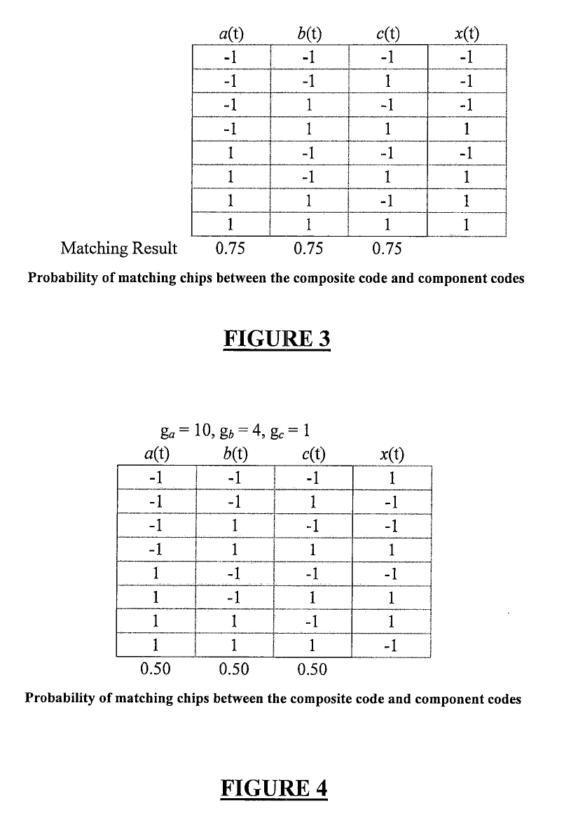

The composite code x(t) has the matching probabilities illustrated in FIG. 3 if gₐ=g_{b}=g_{c}=1. From the graphs of FIG. 3, it will be appreciated that each component BPSK code matches the composite BPSK code 75% (i.e., on average each component code matches the composite code 6 out of 8 chips). By a “match”, it is meant that the product of a component code chip and its corresponding composite code chip is “1”; a mismatch is “−1”. When all 8 chips are matched (i.e., matching probability of 100%), the correlation between a component BPSK code and the composite BPSK code would be:

$${R}_{x , a} = {R}_{x , b} = {R}_{x , c} = \frac{8 ( 1 ) + 0 ( - 1 )}{8} = 1 = 0 dB . \qquad Equation 5$$

This is perfect or “full” correlation. When the matching probability drops below 100%, perfect correlation is no longer achievable. For a matching probability of 75%, the impact on the correlation is shown below:

$${R}_{x , a} = {R}_{x , b} = {R}_{x , c} = \frac{6 ( 1 ) + 2 ( - 1 )}{8} = 0.50 = - 3 dB . \qquad Equation 6$$

Hence, 75% matching probability translates to 3 dB correlation loss. Note that each matching or mismatching chip increases or decreases the correlation, respectively.

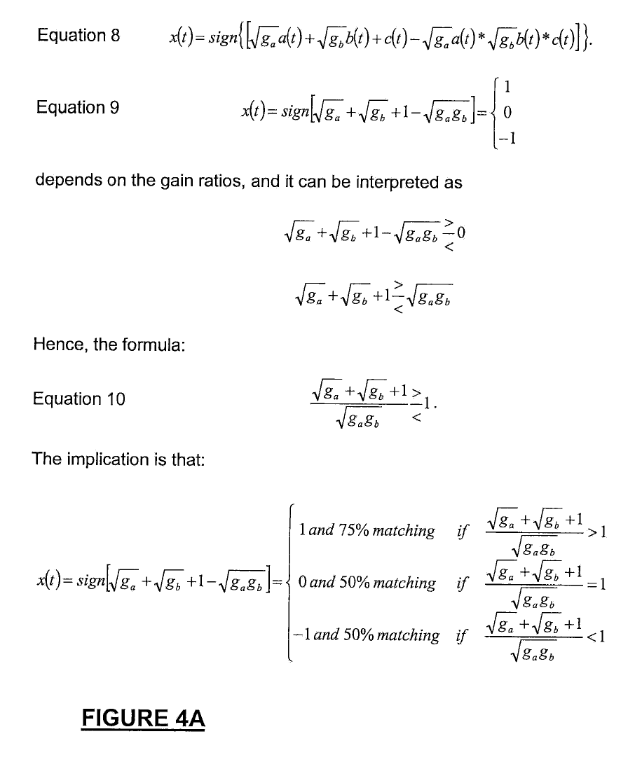

If gₐ and g_{b} vary, the matching probabilities will also vary. For code power ratios gₐ=10, g_{b}=4, and g_{c}=1, the matching probabilities are tabulated at FIG. 4.

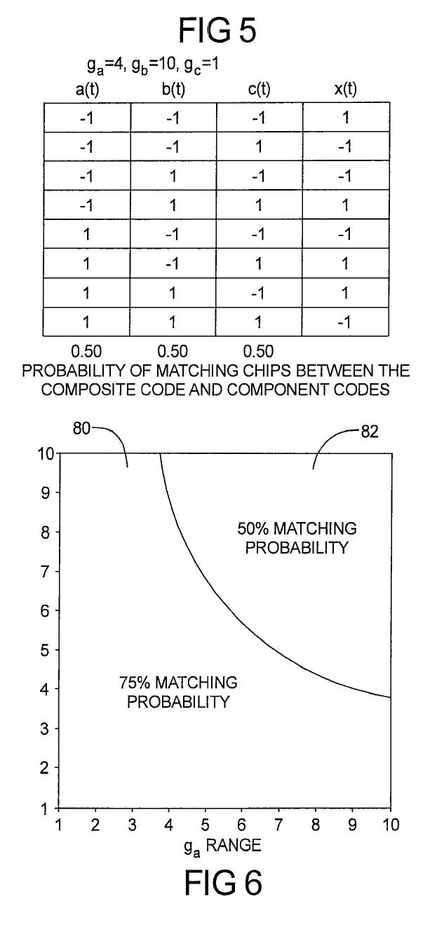

Note that from the tables in FIGS. 3 and 4, x(t) changes from 1 to −1 when a(t)=b(t)=c(t)=1 (or changes from −1 to 1 when a(t)=b(t)=c(t)=−1). Referring to FIG. 5, when swapping gₐ and g_{b}, the same result is achieved. This is expected since \sqrt{gₐ}a(t) and \sqrt{g_{b}}b(t) satisfy the communicative law. The communicative law holds that when one adds or multiplies numbers, the order doesn't matter. Fifty percent matching means on average each component code matches the composite code 4 out of 8 chips. The correlation is reduced to zero:

$${R}_{x , a} = {R}_{x , b} = {R}_{x , c} = \frac{4 ( 1 ) + 4 ( - 1 )}{8} = 0 = - ∞ dB . \qquad Equation 7$$

Since the code power ratios among the component BPSK codes change the correlation between the composite BPSK code and each component BPSK code, it is then essential to ascertain the ranges of gₐ and g_{b} and the corresponding matching probabilities for the component BPSK codes. The development is shown below from Equation 4:

x(t)=sign{[\sqrt{gₐ}a(t)+\sqrt{g_{b}}b(t)+c(t)−\sqrt{gₐ}a(t)*\sqrt{g_{b}}b(t)*c(t)]}. Equation 8

Since x(t) changes from 1 to −1 when a(t)=b(t)=c(t)=1, it can be shown that

$$x ( t ) = sign [ \sqrt{{g}_{a}} + \sqrt{{g}_{b}} + 1 - \sqrt{{g}_{a} {g}_{b}} ] = \{ \begin{matrix}1 \\ 0 \\ - 1\end{matrix} \qquad Equation 9$$

depends on the gain ratios, and it can be interpreted as

$$\sqrt{{g}_{a}} + \sqrt{{g}_{b}} + 1 - \sqrt{{g}_{a} {g}_{b}} \frac{>}{<} 0$$

$$\sqrt{{g}_{a}} + \sqrt{{g}_{b}} + 1 \frac{>}{<} \sqrt{{g}_{a} {g}_{b}}$$

Hence, the formula:

$$\frac{\sqrt{{g}_{a}} + \sqrt{{g}_{b}} + 1}{\sqrt{{g}_{a} {g}_{b}}} \frac{>}{<} 1. \qquad Equation 10$$

The implication is that:

$$\begin{matrix}x ( t ) = sign [ \sqrt{{g}_{a}} + \sqrt{{g}_{b}} + 1 - \sqrt{{g}_{a} {g}_{b}} ] \\ = \{ \begin{matrix}1 and 75 \% matching & if \frac{\sqrt{{g}_{a}} + \sqrt{{g}_{b}} + 1}{\sqrt{{g}_{a} {g}_{b}}} > 1 \\ 0 and 50 \% matching & if \frac{\sqrt{{g}_{a}} + \sqrt{{g}_{b}} + 1}{\sqrt{{g}_{a} {g}_{b}}} = 1 \\ - 1 and 50 \% matching & if \frac{\sqrt{{g}_{a}} + \sqrt{{g}_{b}} + 1}{\sqrt{{g}_{a} {g}_{b}}} < 1\end{matrix}\end{matrix}$$

The above formulas are also presented in FIG. 4A for convenience.

FIG. 6 illustrates the ranges and matching probabilities of each component BPSK code against the composite BPSK code x(t) where cross-hatched area 80 represents an area where 75% matching probability is achieved, and stippled area 82 represents an area where 50% matching probability is achieved. When gₐ=9 and g_{b}=4, then:

$$\begin{matrix}x ( t ) = sign [ \sqrt{{g}_{a}} + \sqrt{{g}_{b}} + 1 - \sqrt{{g}_{a} {g}_{b}} ] \\ = 0\end{matrix} \\ if \frac{\sqrt{{g}_{a}} + \sqrt{{g}_{b}} + 1}{\sqrt{{g}_{a} {g}_{b}}} = 1. \qquad Equation 11$$

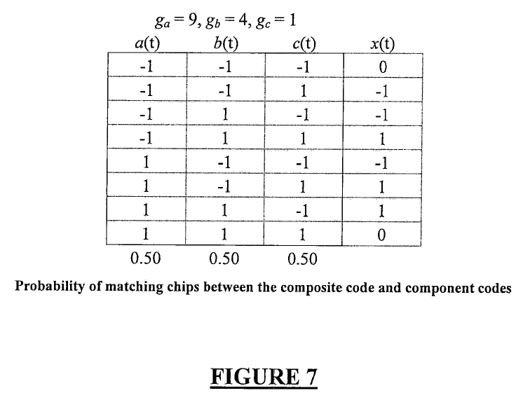

The occurrence of Equation 11 is on the border between areas 80 and 82. Thus, the probability of occurrence is very small and is negligible. The probabilities of the component BPSK codes matching the composite BPSK code x(t) are as illustrated in the table of FIG. 7. Thus, the ranges for gₐ and g_{b} and the corresponding matching probabilities can mathematically be expressed as

$$\frac{\sqrt{{g}_{a}} + \sqrt{{g}_{b}} + 1}{\sqrt{{g}_{a} {g}_{b}}} = \{ \begin{matrix}> 1 & 75 \% matching \\ < 1 & 50 \% matching\end{matrix} .$$

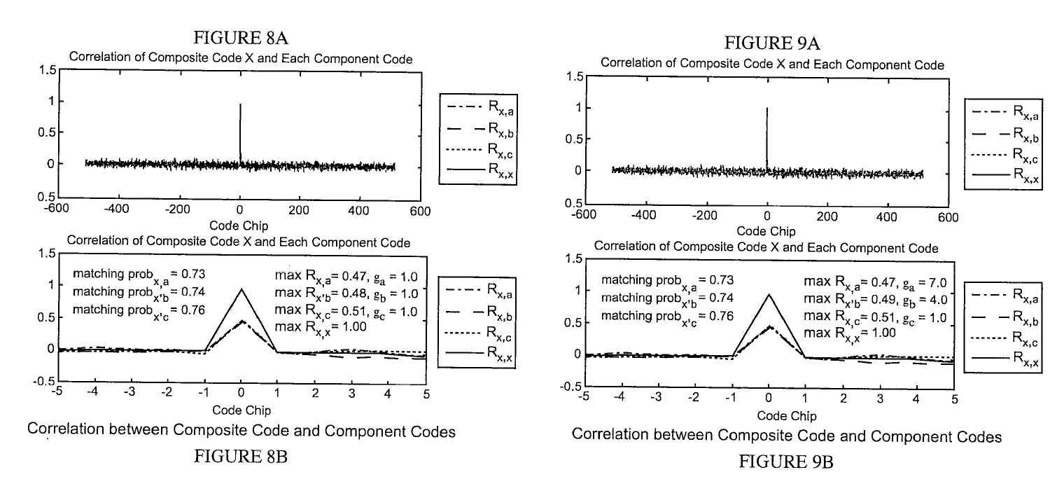

FIGS. 8A,8B, 9A,9B, 10A,10B and 11A,11B demonstrate the relationship between the matching probability and the associated correlation at various code power ratios. These Figures assume infinite bandwidth. Had a filter of a finite bandwidth been applied before correlation takes place, the correlation will be reduced due to out-of-band loss. The amount of reduction depends on the filter bandwidth and the chip rates of the component BPSK codes. FIGS. 8A and 8B are graphs illustrating the correlations of the composite BPSK code with itself and with the component BPSK codes; the correlation of the composite BPSK code with itself has a peak of unity since it matches itself perfectly as it should. The correlations of the composite BPSK code with the component BPSK codes have peaks roughly 0.5 indicating the 75% matching between the composite BPSK code and the component BPSK codes (see Equation 6 below). FIG. 8B is an enlarged version of FIG. 8A focusing on the details of the peaks of these correlations.

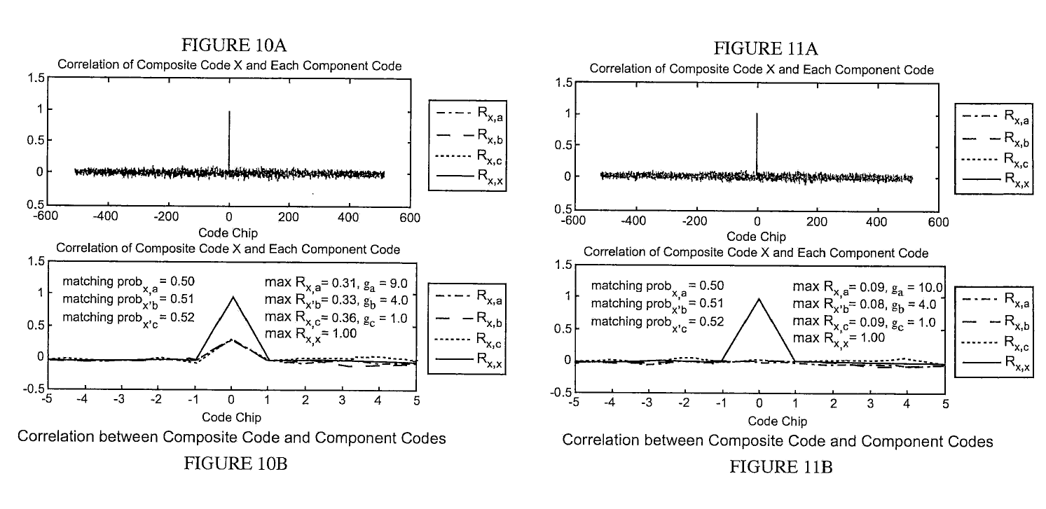

The correlations shown in FIGS. 8B and 9B have code power ratios in the cross-hatched area 80 of FIG. 6 and have a matching probability of roughly 75% as stated in Equation 6. The correlations in FIG. 11B are virtually zero since the code power ratios are well within the stippled area 82 of FIG. 6. The correlations in FIG. 10B are approaching zero since the code power ratios are on the border between cross-hatched 80 and stippled 82 areas in FIG. 6.

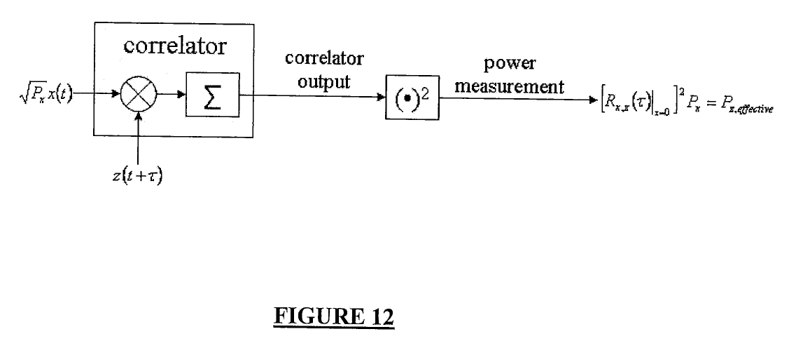

The matching probability for each component BPSK code determines the correlatable power (also known as effective code power) of the component code received at the output of a correlator of each component code where code z(t)=a(t), b(t) or c(t) and Pₓ is the power of the composite BPSK code x(t), Pₓ=Pₐ+P_{b}+P_{c}=(gₐ+g_{b}+1)*P_{c}; as indicated in FIG. 12.

For matching probabilities equal to 75%, the P_{z,effective} is 0.25 of Pₓ for each component BPSK code. This means a total of 0.75=3(0.25) of the total power of composite BPSK code can be recovered and the combining efficiency is equal to 0.75.

$$\begin{matrix}{η}_{z} = \frac{{P}_{z , effective}}{{P}_{x}} = {[ {R}_{x , z} ( τ ) {\vert}_{τ = 0} ]}^{2} & Equation 12 \\ 0.75 = η = {η}_{a} + {η}_{b} + {η}_{c} = 0.25 + 0.25 + 0.25 & Equation 13\end{matrix}$$

This demonstrates via Equation 10 that maintaining the code power ratios gₐ and g_{b} will maintain component BPSK code power efficiencies ηₐ, η_{b} and η_{c} as well as the composite code efficiency η.

Due to the combining efficiency in Equation 13 not being 100%, there is a combining loss. This means the effective code power at the correlator output for each component code will not be P_{z}, but something less P_{z,effective}<P_{z}. If P_{z} is desired at the correlator output of each component code (i.e., P_{z} is expected as the effective code power at the correlator output), then the difference between P_{z,effective} (the effective code power before component code power compensation) and P_{z} (the effective code power after component code compensation) needs to be made up by some power compensation to the code. The code power compensation can be done for each component code.

For the composite code, the additional power needed for compensation is calculated as follows:

$${P}_{compensation} = \frac{1}{η} {P}_{x} - {P}_{x} \qquad Equation 14$$

This is equivalent to boosting the composite BPSK code power by a gain (1/η), and the compensated composite BPSK code power may be represented by the equation:

$$\frac{1}{η} {P}_{x} = {P}_{x} + {P}_{compensation} = {P}_{x} + ( \frac{1}{η} {P}_{x} - {P}_{x} ) . \qquad Equation 15$$

Note that adding compensation power and maintaining code power ratios do not change the efficiencies shown in Equations 12 and 13. The effective code power for component code a(t) after compensation can be calculated to be:

$${η}_{a} [ {P}_{x} + ( \frac{1}{η} {P}_{x} - {P}_{x} ) ] = {η}_{a} \frac{{P}_{x}}{η} = \frac{{P}_{a , effective}}{η} = {P}_{a} . \\ ( 1 ) \qquad \text{Equation 16}$$

Likewise for the other two component codes:

$$\begin{matrix}{η}_{b} [ {P}_{x} + ( \frac{1}{η} {P}_{x} - {P}_{x} ) ] = {η}_{b} \frac{{P}_{x}}{η} = \frac{{P}_{b , effective}}{η} = {P}_{b} \\ ( 2 ) & \text{Equation 17} \\ {η}_{c} [ {P}_{x} + ( \frac{1}{η} {P}_{x} - {P}_{x} ) ] = {η}_{c} \frac{{P}_{x}}{η} = \frac{{P}_{c , effective}}{η} = {P}_{c} . \\ ( 3 ) & \text{Equation 18}\end{matrix}$$

If the composite code can be made available as the local replica in the correlator (i.e., z(t)=x(t)), the total power of the composite BPSK code x(t) can be recovered. For matching probabilities equal to 50%, no code power can be recovered. This feature can be used to identify that gain weighted combining of three component BPSK Codes is the option being used among a number of different code combining methodologies. Note that the code combining above may also be applied to component BPSK codes of different chip rates.

It will be appreciated that a code power and chip rate for each component BPSK code could also be remotely programmed to tailor the system 10 to meet the needs of a specific application.

While various embodiments have been described, those skilled in the art will recognize modifications or variations which might be made without departing from the present disclosure. The examples illustrate the various embodiments and are not intended to limit the present disclosure. Therefore, the description and claims should be interpreted liberally with only such limitation as is necessary in view of the pertinent prior art.

What is claimed is:

1. A method for combining first, second and third component binary phase shift keying (BPSK) codes to form one composite BPSK code, comprising:
gain weighting each of said first, second and third component BPSK codes by its respective code power ratio to form first, second and third gain weighted codes;
processing the first, second and third component BPSK codes using the code power ratios to form a composite BPSK code, where the composite BPSK code has at least a fifty percent probability of matching each one of said component BPSK codes.

2. The method of claim 1, where the composite BPSK code has a seventy-five percent probability of matching each one of said component BPSK codes.

3. The method of claim 1, wherein gain weighting of said first, second and third BPSK codes comprises the operations:
assigning a(t) to represent said first component BPSK code, where a(t) is a random BPSK code equally likely to be +1 or −1, and has a highest code power of said three component BPSK codes;
assigning b(t) to represent said second component BPSK code, where b(t) is a random BPSK code equally likely to be +1 or −1, and has a second highest code power of said three component BPSK codes;
assigning c(t) to represent said third component BPSK code, where c(t) is a random BPSK code equally likely to represent +1 or −1, and has a code power no more than that of the other two component BPSK codes;
determining code power ratios using corresponding gain weighting formulas:
$${g}_{a} = \frac{code power of a ( t )}{code power of c ( t )}$$
$${g}_{b} = \frac{code power of b ( t )}{code power of c ( t )}$$
$${g}_{c} = \frac{code power of c ( t )}{code power of c ( t )} = 1.$$

4. The method of claim 3, where wherein gₐ, g_{b} and g_{c} are arranged such that:
gₐ≧g_{b}≧g_{c}=1.

5. The method of claim 4, wherein said composite BPSK code is represented by a term x(t), and wherein x(t) is determined by the formula:
x(t)=sign{[\sqrt{gₐ}a(t)+\sqrt{g_{b}}b(t)+c(t)−\sqrt{gₐ}a(t)*\sqrt{g_{b}}b(t)*c(t)]}.

6. The method of claim 4, further comprising determining a power efficiency of each said component BPSK code.
$${η}_{z} = \frac{{P}_{z , effective}}{{P}_{x}} = {[ {R}_{x , z} ( τ ) {\vert}_{τ = 0} ]}^{2}$$

7. The method of claim 6, wherein:
Pₐ is a power of component code a(t);
P_{b} is a power of component code b(t);
P_{c} is a power of component code c(t);
Pₓ is a power of composite code x(t); and
Pₓ=Pₐ+P_{b}+P_{c}=(gₐ+g_{b}+1)*P_{c}.

8. The method of claim 6, further comprising compensating for a reduction in effective code power of said composite BPSK code.

9. The method of claim 5, wherein each of the plurality of component BPSK codes is represented in the composite BPSK code with a common power efficiency.

10. The method of claim 5, wherein a combining loss resulting from combining the plurality of component BPSK codes is substantially the same for each of the plurality of component BPSK codes.

11. The method of claim 5, wherein the code power and chip rate of each of the plurality of component BPSK codes is remotely programmable.

12. A method for combining first, second and third component binary phase shift keying (BPSK) codes to form one composite BPSK code, comprising:
gain weighting of said first, second and third component BPSK codes by the formulas using a code power ratio of each said component BPSK code as follows:
$${g}_{a} = \frac{code power of a ( t )}{code power of c ( t )}$$
$${g}_{b} = \frac{code power of b ( t )}{code power of c ( t )}$$
$${g}_{c} = \frac{code power of c ( t )}{code power of c ( t )} = 1.$$
where a(t) represents said first component BPSK code, and \sqrt{gₐ}a(t) comprises a gain weighted first component BPSK code,
where b(t) represents said second component BPSK code, and \sqrt{g_{b}}b(t) comprises a gain weighted second component BPSK code,
where c(t) represents said third component BPSK code, and
where \sqrt{g_{c}}c(t) comprises a gain weighted third component BPSK code,
selecting an order of said component BPSK codes such that gₐ≧g_{b}≧g_{c}, and g_{c} is set equal to 1; and
processing the first, second and third gain weighted component BPSK codes to form a single, composite BPSK code that represents the three component BPSK codes.

13. The method of claim 12, wherein said composite BPSK code has a probability of matching each one of said component BPSK codes that is greater than or equal to fifty percent.

14. The method of claim 12, where the composite BPSK code has approximately a fifty percent to seventy-five percent probability of matching each one of said component BPSK codes.

15. The method of claim 14, wherein said composite BPSK code is represented by a term x(t), and wherein x(t) is determined by the formula:
x(t)=sign{[\sqrt{gₐ}a(t)+\sqrt{g_{b}}b(t)+c(t)−\sqrt{gₐ}a(t)*\sqrt{g_{b}}b(t)*c(t)]}.

16. The method of claim 15, further comprising determining a power efficiency of each said component BPSK code to assist in determining a level of power compensation to be applied to each said component BPSK code to account for a power loss experienced by each said component BPSK code.

17. The method of claim 16, wherein a code power of the composite BPSK code x(t) is determined by:
where Pₐ is a power of component code a(t);
where P_{b} is a power of component code b(t);
where P_{c} is a power of component code c(t);
where Pₓ is a power of composite code x(t); and
Pₓ=Pₐ+P_{b}+P_{c}=(gₐ+g_{b}+1)*P_{c}.

18. The method of claim 17, further comprising compensating for a reduction in code power of said composite BPSK code.

19. A method for combining first, second and third component binary phase shift keying (BPSK) codes to form one composite BPSK code, comprising:
gain weighting each of said first, second and third component BPSK codes such that:
a(t) represents said first component BPSK code, and \sqrt{gₐ}a(t) comprises a gain weighted first component BPSK code;
b(t) represents said second component BPSK code, and \sqrt{g_{b}}b(t) comprises a gain weighted second component BPSK code;
c(t) represents said third component BPSK code, and \sqrt{g_{c}}c(t) comprises a gain weighted third component BPSK code;
designating said component BPSK codes such that gₐ≧g_{b}≧g_{c}, and g_{c} is set equal to 1; and
processing the first, second and third gain weighted component BPSK codes in accordance with an algorithm:
x(t)=sign{[\sqrt{gₐ}a(t)+\sqrt{g_{b}}b(t)+c(t)−\sqrt{gₐ}a(t)*\sqrt{g_{b}}b(t)*c(t)]}.
where x(t) represents said composite BPSK code that is representative of the three component BPSK codes a(t), b(t) and c(t).

20. The method of claim 19, wherein said first, second and third weightings of component BPSK codes gₐ, g_{b}, and g_{c}, respectively, are determined in accordance with the algorithms:
$${g}_{a} = \frac{code power of a ( t )}{code power of c ( t )}$$
$${g}_{b} = \frac{code power of b ( t )}{code power of c ( t )}$$
$${g}_{c} = \frac{code power of c ( t )}{code power of c ( t )} = 1.$$

21. The method of claim 19, further comprising determining a power efficiency of each said component BPSK code.

22. The method of claim 21, wherein a code power of the composite BPSK code x(t) is determined by:
Pₓ=Pₐ+P_{b}+P_{c}=(gₐ+g_{b}+1)*P_{c}.
where Pₐ is a power of component BPSK code a(t);
where P_{b} is a power of component BPSK code b(t);
where P_{c} is a power of component BPSK code c(t);
where Pₓ is a power of composite BPSK code x(t); and

23. A system for generating a single, composite binary phase shift keying (BPSK) that is representative of three component BPSK codes, the system comprising:
a pair of square root determining circuits;
a first pair of multiplier circuits responsive to said square root determining circuits;
a second pair of multiplier circuits responsive in part to said first pair of multiplier circuits;
first and second summing circuits responsive in part to said first pair of multiplier circuits;
a third summing circuit responsive to outputs of said first and second summing circuits;
a zero threshold circuit for comparing an output of said third summing circuit against a zero threshold; and
said square root determining circuits, said multiplier circuits, said summing circuits and said zero threshold circuit being configured to execute an algorithm comprising:
x(t)=sign{[\sqrt{gₐ}a(t)+\sqrt{g_{b}}b(t)+c(t)−\sqrt{gₐ}a(t)*\sqrt{g_{b}}b(t)*c(t)]}
where a(t) represents a first component BPSK code, and \sqrt{gₐ}a(t) comprises a gain weighted first component BPSK code;
where b(t) represents said second component BPSK code, and \sqrt{g_{b}}b(t) comprises a gain weighted second component BPSK code;
where c(t) represents said third component BPSK code, and \sqrt{g_{c}}c(t) comprises a gain weighted third component BPSK code (since g_{c}=1, the gain weighted third component BPSK code is c(t)); and
where an order of said component BPSK codes has been selected such that gₐ≧g_{b}≧g_{c}, and g_{c} is set equal to 1.
